(19) United States
(12) Patent Application Publication
(10) Pub. No.: US 2025/0347468 A1
(43) Pub. Date: Nov. 13, 2025

(54) SYSTEM AND METHOD FOR GENERATING ELECTRICITY FROM RADIANT HEAT IN METAL RECYCLING PROCESSES

(71) Applicant: James Todd Wagner, Fort Lauderdale, FL (US)

(72) Inventor: James Todd Wagner, Fort Lauderdale, FL (US)

(21) Appl. No.: 19/204,879

(22) Filed: May 12, 2025

Related U.S. Application Data
(60) Provisional application No. 63/646,735, filed on May 13, 2024.

(51) Int. Cl. F27B 14/08; B09B 3/40; H10N 10/00

(52) U.S. Cl. CPC F27B 14/08; B09B 3/40; H10N 10/00

(57) ABSTRACT

A system and method generate electricity from radiant heat emitted by a heated Ladle in metal recycling operation. The Ladle, either preheated empty (System-1) or containing liquid metal (System-2), radiates heat at between 200° C. and 2000° C. System-1 and System-1 are identified as Waste-Heat-Sources. Radiant heat from Waste-Heat-Sources is captured by a proximate Heat-to-Electricity Generator (‘HTE-Generator’). The HTE-Generator converts radiant heat into electrical energy, powering the recycling process and reducing factory thermal load to lower air-conditioning energy costs. Configurations include fixed, overhead hoist-mounted, scissor-lift-mounted, or overhead and surrounding setups.

### PRIORITY CLAIM

This application claims priority to U.S. Provisional Patent Application No. 63/646, 735, filed May 13, 2024, titled “Metal Recycling Waste Heat Converter,” the entire contents of which are incorporated herein by reference.

### FIELD OF THE INVENTION

This invention relates to energy recovery, specifically capturing radiant heat from a heated Ladle in metal recycling processes to generate electricity, improving energy efficiency and sustainability.

### DEFINITIONS

Liquid-Metal: Metal of any chemical alloy that has been heated into a liquid state at temperatures that typically range between 650° C.-1700° C. For example, liquid Aluminum is recycled via melting scrap aluminum at temperatures between 660° C. and 800° C. For example, liquid Steel is recycled via melting scram steel at temperatures between 1450° C. and 1700° C. depending upon the type of furnace being used and the alloy being melted.

Refractory-Brick: Industry standard material typically of ceramic composition that is designed to resist the extremely high temperatures of liquid metal.

Ladle: A steel container that is typically cylindrical in shape with one end of the cylinder closed off. The opposing end of the cylinder is open, and liquid metal is poured into the open end. The Ladle typically has metal elements attached to the cylindrical shape to facilitate hoisting the Ladle and metal elements to facilitate holding the Ladle either with the open end facing in a direction that facilitates the particular manufacturing stage of the metal recycling. The Ladle typically features a metal door at the bottom of the Ladle, which is opened to allow the liquid metal to flow out of the Ladle. The Ladle will have Refractory-Bricks installed in the interior of the Ladle, when it is prepared to receive Liquid-Metal.

Preheated-Ladle: A Ladle that has been heated to at least 200° C.

Filled-Ladle: The combination of a Ladle filled with Liquid-Metal. Both the Ladle and Liquid metal will be at temperatures above 200° C. and below 2000° C.

Waste-Heat: Electromagnetic thermal energy emitted by the Ladle and Liquid-Metal, that is typically radiated out into the recycling facility and extracted via air-conditioning systems.

Heat-to-Electricity Generator: Any device converting radiant heat to electricity, broadly defined.

Heat-Exchanger: A device standard in the art such as the radiator on a vehicle or the radiant energy collecting panel of a Heat-to-Electricity Generator. The Heat-Exchanger may be connected to the turbine, condenser, and compressor portions of a Rankine Cycle Heat-to-Electricity Generator via tubes carrying the working fluid of the Heat-to-Electricity Generator. Heat-Exchangers, common to the art, comprise air-to-air heat exchangers, air-to-fluid heat exchangers, and fluid-to-fluid heat exchangers. Air-to-Fluid heat exchangers will be most common for this present invention due to the temperature ranges and the efficient Rankine cycle that will be most often used to convert the radiant heat to electricity.

Overhead Hoist: Equipment for vertical positioning via chains or cables.

Scissor-Lift: A floor-mounted device for vertical adjustment.

### BACKGROUND OF THE INVENTION

Metal recycling mills produce substantial quantities of high-temperature waste heat, much of which is radiated into the surrounding environment and remains unused. In metal recycling, sorted metals are placed in vessels and melted in large furnaces using induction, blast, or electric furnaces depending on the metal being recycled.

A vessel may be sized to hold tens to hundreds of tons of steel. The furnace heats the steel into a liquefied metal. For instance, carbon steel becomes a liquefied metal at a melting point between 1150° C. and 1425° C. Additives are typically added to the liquefied metal to obtain an even distribution or to change the metal into a different type of steel. The vessels are typically lined with a refractory material which can still radiate heat at thousands of degrees Fahrenheit. The vessels are moved with overhead cranes to molds or casters. In larger plants the vessels are mounted on rails to carry the material on tracks. The vessel described herein is commonly described as a “Ladle” in the art. For the remainder of this Patent Application, the vessel will be identified by the word, Ladle.

High heat radiated from the Ladles carrying the liquified metal may be drawn away from the Ladle by use of exhaust or fan systems and air conditioning units. The fans and air conditioning systems require a large amount of electricity to operate in order to dispel excess heat to maintain a safe factory temperature for the people working inside the building. Since the liquified metal will have been heated by an external energy source and held inside the vessel at very high temperatures, the resulting radiant heat is wasted by the radiation absorbed by walls, nearby machines, and people working in the mill.

There is a need for an efficient energy conversion system capable of capturing radiant heat from a Ladle for the purpose of converting the radiant heat into electrical energy in a sustainable and cost-effective manner, particularly in high-temperature industrial processes such as metal recycling.

Simply insulating the Ladle and Liquid Metal only serves to slow the escape of heat, is short-lived due to the extreme temperatures, and does nothing to convert the valuable heat into usable electricity.

In metal recycling, such as steel, aluminum, or titanium production, a Ladle holds liquid metal (500-1700° C.) or is preheated empty (˜200-1400° C.) to maintain Refractory-Brick stability. This heat is currently radiated out to the atmosphere of the recycling facility, increasing factory thermal load and requiring energy-intensive air-conditioning to maintain temperatures that are safe for human operators of the recycling facility. Existing Heat-to-Electricity Generators recover heat from combustion or exhaust but are not combined with a Preheated-Ladle or Filled-Ladle to capture radiant heat in metal recycling. No prior art teaches this combination.

### PRIOR ART

The prior art includes systems for waste heat recovery, such as directing hot air over incoming scrap metal to preheat the scrap metal that will be melted; but no prior art in metal recycling combines a Preheated-Ladle or Filled-Ladle with a Heat-to-Electricity Generator to capture radiant heat in metal recycling or address thermal load reduction. Eight patents are summarized below, which convert natural or waste heat to electricity. The invention does not describe a new Heat-to-Electricity Generator. The invention describes a novel use of any Heat-to-Electricity Generator in a metal recycling factory within proximity to a Preheated-Ladle or Filled-Ladle.

U.S. Pat. No. 9,003,798 B2 (Yanagi et al., 2015): Organic Rankine Cycle (ORC) system for low-temperature heat (60° C.+). Features a plate heat exchanger, SES36 organic fluid (pentafluorobutane/perfluoropolyether), high/low-pressure screw expanders with bypass line, generator, condenser. Designed for conductive/convective heat (e.g., ship engine exhaust, geothermal brine).

U.S. Pat. No. 8,763,398 B2 (Erickson et al., 2014): ORC with recuperator for waste heat (150-300° C.). Includes heat exchanger, turbine, generator. Designed for conductive heat. This device could be the Heat-to-Electricity Generator portion of the present invention.

U.S. Pat. No. 4,228,657 A (Leonhardt et al., 1980): Traditional Rankine Cycle (TRC) for exhaust heat (300° C.+). Heat exchanger drives steam turbine, generator. This device could be the Heat-to-Electricity Generator portion of the present invention.

U.S. Pat. No. 7,987, 674 B2 (Hustad et al., 2011): TRC with heat recovery steam generator (HRSG) for gas turbine exhaust. Large HRSG unfit for Ladle combination and does not secondarily create factory cooling.

U.S. Pat. No. 5,570,071 (Stein Industrie, 1996): TRC for combined cycle plants. HRSG uses exhaust (400-600° C.) for steam turbine. This device could be the Heat-to-Electricity Generator portion of the present invention.

U.S. Pat. No. 6,360,284 B1 (Sammons, 2002): Kalina cycle for low-grade heat (100-300° C.). Binary fluid, heat exchanger, turbine. This device could be the Heat-to-Electricity Generator portion of the present invention.

U.S. Pat. No. 9,458,734 B2 (Cogswell et al., 2016): Supercritical CO2 (sCO2) cycle for heat above 200° C. Costly exchanger, not integrated with a Ladle. No thermal load focus.

U.S. Pat. No. 6,920,764 B2 (Department of Energy, 2005): Thermophotovoltaic (TPV) system for high-temperature heat (1000-1500° C.). Radiant collector with TPV cell could be the Heat-to-Electricity Generator of the present invention if positioned in a metal recycling factory near where Ladles traverse or are held steady.

These prior-art systems rely on conductive, convective, and radiant heat from exhaust gases or other sources, not radiant heat from a metal recycling process including a Preheated-Ladle or Filled-Ladle. The present invention utilizes technologies such as the stated prior-art, ORC, TRC, and TPV as one component in the Preheated-Ladle Configuration and Filled-Ladle Configuration. The present invention innovates by integrating any Heat-to-Electricity Generator with the liquid-metal-processing heat source of a Preheated-Ladle or Filled-Ladle, enabling both electricity generation and reduced air-conditioning energy costs.

### SUMMARY OF THE INVENTION

The invention provides a system and method for generating electricity from radiant heat emitted by a Preheated-Ladle or Filled-Ladle in metal recycling mills. A Heat-to-Electricity Generator, positioned proximate to the Ladle, absorbs radiant heat (200-2000° C.) and converts it to electrical energy. Configurations include fixed, overhead hoist-mounted, scissor-lift-mounted, or overhead/surrounding setups to optimize heat capture. The system powers the recycling process itself and reduces thermal load, lowering air-conditioning energy consumption.

The novelty lies in combining a Preheated-Ladle or Filled-Ladle with a Heat-to-Electricity Generator, a solution not taught by prior art, enhancing efficiency and sustainability.

An advantage of the invention is the recovery of radiant heat that is presently wasted to the environment from the very-high-temperature metal recycling process. Thus, simultaneously generating free electricity out of the existing recycling process and minimizing the electricity input requirements to the factory air conditioning system.

### BRIEF DESCRIPTION OF DRAWINGS

FIG. 1: Schematic of a fixed-position Heat-to-Electricity Generator proximate to a Preheated-Ladle Configuration.

FIG. 2: Schematic of an overhead hoist-mounted Heat-to-Electricity Generator with vertical adjustment for a Preheated-Ladle Configuration.

FIG. 3: Schematic of a scissor-lift-mounted Heat-to-Electricity Generator with vertical adjustment for a Preheated-Ladle Configuration.

FIG. 4: Schematic of a fixed-position Heat-to-Electricity Generator proximate to a Filled-Ladle Configuration.

FIG. 5: Schematic of an overhead hoist-mounted Heat-to-Electricity Generator with vertical adjustment for a Filled-Ladle Configuration.

FIG. 6: Schematic of a scissor-lift-mounted Heat-to-Electricity Generator with vertical adjustment for a Filled-Ladle Configuration.

### DETAILED DESCRIPTION OF THE INVENTION

The invention generates electricity from radiant heat emitted by a heated Ladle in metal recycling, either in a Preheated-Ladle Configuration (˜200° C.-1400° C.) or a Filled-Ladle Configuration (500-1700° C.). A Heat-to-Electricity Generator, positioned proximate to the Ladle, absorbs radiant heat and converts it to electrical energy, powering the recycling process and reducing factory thermal load to lower air-conditioning energy consumption. Presently, the air conditioning system is required to ensure safe temperatures for human operators of the steel recycling mill.

The temperature ranges are broad because metal recycling is done for several metals, with the most common being aluminum and steel. Each metal has its distinct melting point, thus the recycling operating temperatures align with the metal being manufactured and recycled. Higher temperature metal recycling, such as steel, will feature radiant heat-absorbing panels located farther away from the focused heat source than the lower-temperature metal recycling, such as aluminum.

The invention's novelty lies in combining a Preheated-Ladle or Filled-Ladle with a Heat-to-Electricity Generator to capture waste radiant heat in metal recycling, where no such system exists. This combination generates electricity and reduces thermal load, providing dual energy savings not taught by prior art.

The system comprises a heated Ladle (Preheated-Ladle Configuration or Filled-Ladle Configuration) and a Heat-to-Electricity Generator positioned to absorb radiant heat (200-2000° C.) and generate electricity. Without this invention, radiant heat is wasted, increasing cooling costs. Configurations include fixed, overhead hoist-mounted, scissor-lift-mounted, or overhead/surrounding setups to optimize heat capture. The electricity powers recycling operations, and thermal load reduction lowers air-conditioning energy. The

Heat-to-Electricity Generator will not come into physical contact with the Ladle, as that would parasitically draw heat energy away from the liquid metal, which must remain in a liquid state while contained in the Ladle.

The Heat-Exchanger will primarily absorb radiant heat, but convective heat transfer via the very hot air surrounding the Ladle will also be absorbed by the Heat-Exchanger for use in generating electricity. The system does not differentiate between radiant heat and convective heat absorption. The system will avoid direct heat conduction away from the Ladle, but this cannot be fully prevented due to the entropic nature of heat that dissipates from high temperature zones to low temperature zones.

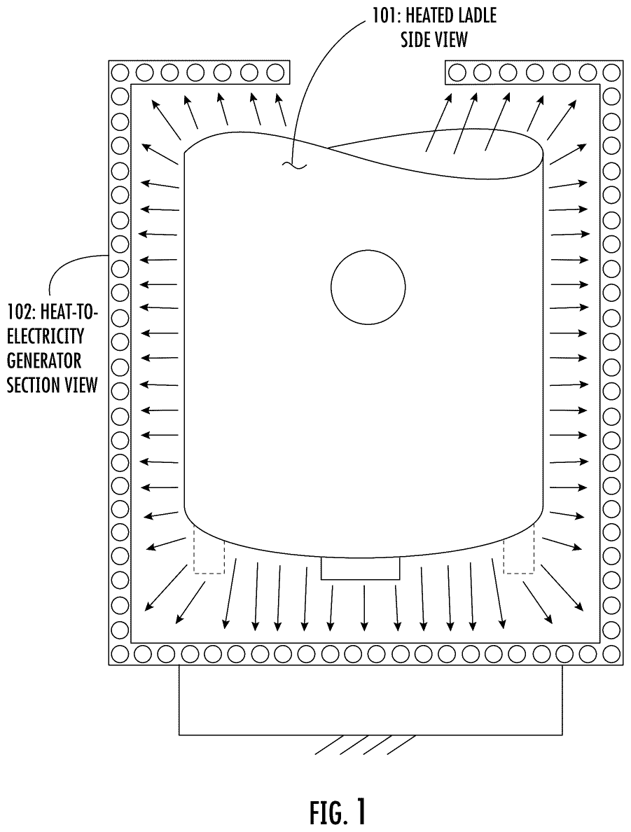

The present invention encompasses a plurality of embodiments configured to optimize the capture of radiant heat from a heated Ladle in a metal recycling process, wherein the Ladle is configured as either a Preheated-Ladle Configuration or a Filled-Ladle Configuration. Each embodiment integrates a Heat-to-Electricity Generator proximate to the Ladle to absorb radiant heat and convert it into electrical energy, thereby powering the recycling process and reducing factory thermal load to decrease air-conditioning energy consumption. The embodiments described herein include fixed-position, overhead hoist-mounted, scissor-lift-mounted, and overhead/surrounding configurations, each tailored to maximize heat capture efficiency while accommodating the operational constraints of metal recycling mills. The embodiments are illustrated in FIGS. 1 through 6 and are described with reference to the Preheated-Ladle Configuration (˜200° C.-1400° C.) and the Filled-Ladle Configuration (500-1700° C.).

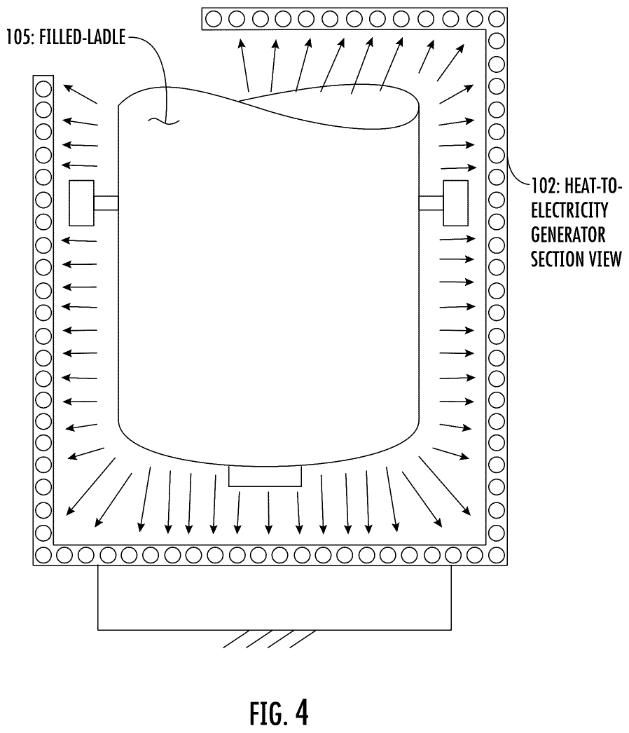

In a first embodiment, depicted in FIGS. 1 and 4, the Heat-to-Electricity Generator is located within the metal recycling mill and may move to various locations within the metal recycling mill where the Ladle is located during the metal melting process. The term “near” is used in a position near where the Ladle is located to define the distance determined by the specific application to yield the ideal working temperature for the Heat-Exchanger within the Heat-to-Electricity Generator. The specific distance between the Ladle and the Heat-Exchanger will vary due to space constraints and the design integrity of efficiently utilizing radiant heat to convert a liquid to a gas in a Heat-Exchanger while maintaining the structural integrity of the Heat-Exchanger. In the Preheated-Ladle Configuration (FIG. 1), the Ladle is a Preheated-Ladle, maintained at a temperature range of approximately 200° C. to 1400° C. to ensure Refractory-Brick stability when the Liquid-Metal is poured into the Ladle, radiating heat that is captured by the Heat-Exchanger within the Heat-to-Electricity Generator. In the Filled-Ladle Configuration (FIG. 4), the Ladle is a Filled-Ladle containing liquid metal, such as 50,000 pounds of molten steel at approximately 1593° C., emitting intense radiant heat that is absorbed by the Heat-Exchanger. The mode for energy transfer is radiant, thus direct contact between the Ladle and the Heat-to-Electricity Generator is not required; however, acceptable if one or more discrete points on the Heat-to-Electricity Generator are in direct contact with the Ladle. The Ladle may rest on a support that positions the Ladle optimally in relation to the Heat-to-Electricity Generator, ensuring an optimal distance, such as approximately 0.5 meters, for radiant heat absorption while minimizing conductive heat losses that could parasitically draw heat from the liquid metal.

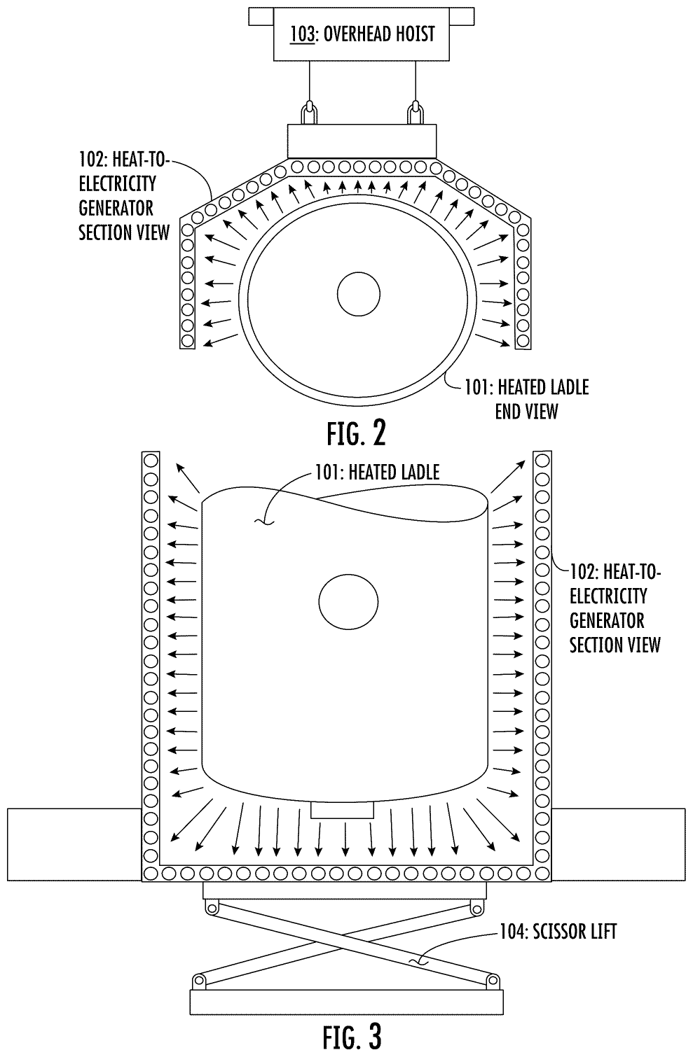

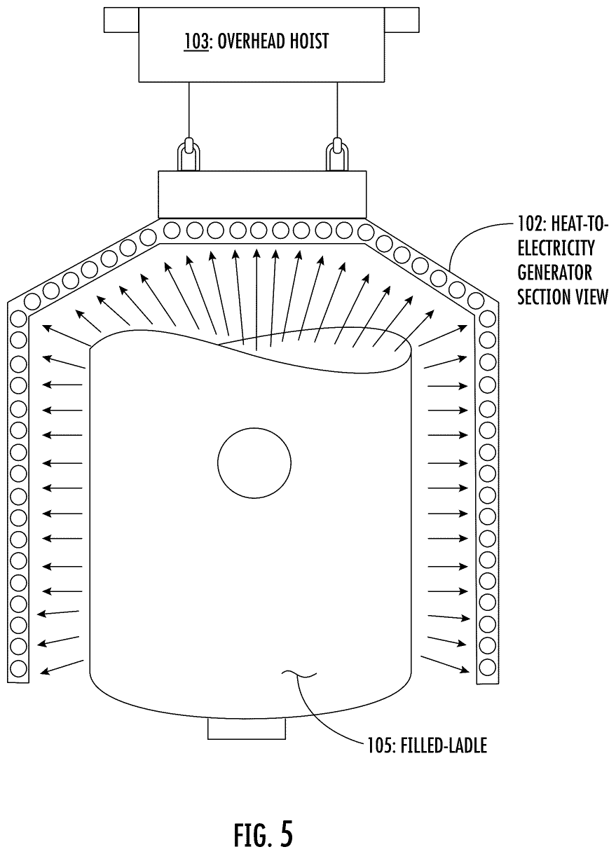

In a second embodiment, illustrated in FIGS. 2 and 5, the Heat-to-Electricity Generator is located within the metal recycling mill and may move to various locations within the metal recycling mill where the Ladle is located during the metal melting process. The Heat-to-Electricity Generator is attached to an Overhead Hoist that moves the Heat-to-Electricity Generator toward the surface of the Ladle to initiate and maintain the radiant heat absorption process. The Overhead Hoist may play an active role in moderating the heat absorbed by the Heat-to-Electricity Generator by bringing the Heat-Exchanger closer to and farther away from the Ladle in response to varying levels of radiant heat energy emanating from the Ladle. In the Preheated-Ladle Configuration (FIG. 2), the Ladle is a Preheated-Ladle, radiating heat at 200° C. to 1400° C., and the Overhead Hoist adjusts the Heat-to-Electricity Generator's position to maintain an optimal distance, such as approximately 0.5 meters, for capturing radiant heat while protecting the Heat-Exchanger from excessive thermal stress. In the Filled-Ladle Configuration (FIG. 5), the Ladle is a Filled-Ladle containing liquid metal at 500° C. to 1700° C., and the Overhead Hoist positions the Heat-to-Electricity Generator to optimize radiant heat absorption from the intense heat source. The Heat-Exchanger within the Heat-to-Electricity Generator absorbs radiant heat, converting it into electrical energy through a thermodynamic cycle, such as an Organic Rankine Cycle (ORC) or Thermophotovoltaic (TPV) system, while also capturing incidental convective heat from the surrounding hot air.

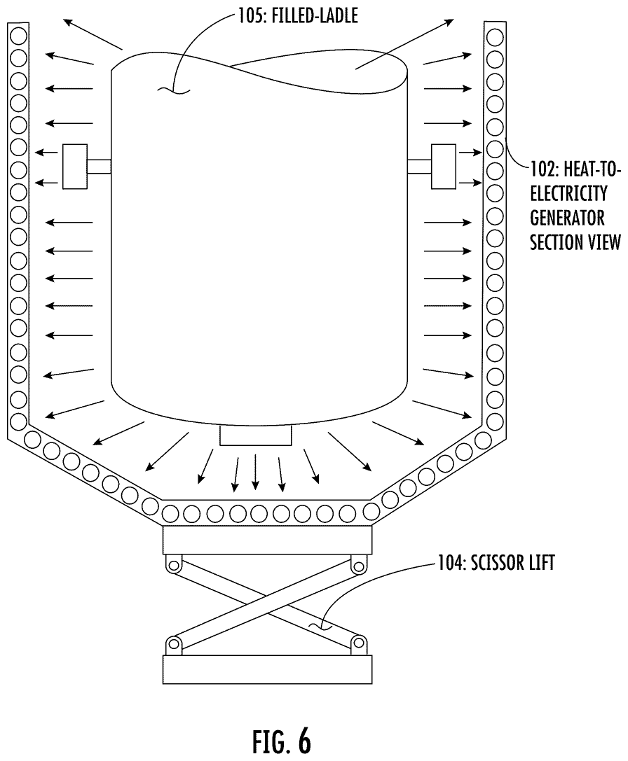

In a third embodiment, shown in FIGS. 3 and 6, the Heat-to-Electricity Generator is located within the metal recycling mill and may move to various locations within the metal recycling mill where the Ladle is located during the metal melting process. The Heat-to-Electricity Generator is attached to a Scissor-Lift that raises the Heat-to-Electricity Generator toward the lower surface of the Ladle to initiate and maintain the radiant heat absorption process. The Scissor-Lift may play an active role in moderating the heat absorbed by the Heat-to-Electricity Generator by bringing the Heat-Exchanger closer to and farther away from the Ladle in response to varying levels of radiant heat energy emanating from the Ladle. In the Preheated-Ladle Configuration (FIG. 3), the Ladle is a Preheated-Ladle, radiating heat at 200° C. to 1400° C., and the Scissor-Lift adjusts the Heat-to-Electricity Generator's position to an optimal distance, such as approximately 0.5 meters, to capture radiant heat while ensuring the longevity of the Heat-Exchanger. In the Filled-Ladle Configuration (FIG. 6), the Ladle is a Filled-Ladle containing liquid metal at 500° C. to 1700° C., such as 50,000 pounds of molten steel at approximately 1593° C., and the Scissor-Lift positions the Heat-to-Electricity Generator to maximize radiant heat absorption. The Heat-Exchanger absorbs radiant heat, supplemented by convective heat from the surrounding air, and converts it into electrical energy through a suitable thermodynamic process.

In a fourth embodiment, the Heat-to-Electricity Generator is configured to partially or fully surround the Ladle, maximizing radiant heat absorption. In the Preheated-Ladle Configuration, the Heat-to-Electricity Generator is positioned overhead or around the Preheated-Ladle, which radiates heat at 200° C. to 1400° C. to maintain Refractory-Brick stability, capturing a larger surface area of emitted radiant heat. The Heat-Exchanger, designed with a radiant energy-absorbing surface, surrounds the Preheated-Ladle to intercept heat that would otherwise dissipate into the recycling mill environment. In the Filled-Ladle Configuration, this configuration is adapted to position the Heat-to-Electricity Generator strategically to capture radiant heat from the liquid metal at 500° C. to 1700° C. while maintaining a safe distance to protect the generator's components from extreme temperatures. The Heat-to-Electricity Generator converts the absorbed radiant heat into electrical energy, powering the recycling process or other mill operations. This embodiment is particularly effective for Preheated-Ladle Configurations due to the lower temperature range, which allows closer positioning of the generator, but its adaptability to Filled-Ladle Configurations ensures broad applicability. By capturing a significant portion of the radiant heat, this embodiment substantially reduces the factory thermal load, thereby lowering air-conditioning energy costs and enhancing the sustainability of the metal recycling process.

The system operates when the Ladle and Liquid-Metal radiates heat at 200-1700° C. Temporarily, the liquid metal may rise in temperature up to 2000° C. or more for the short time span and localized volume where the transition of the solid metal to a liquid is occurring. The Heat-to-Electricity Generator absorbs radiant heat, converting it to electricity for recycling or other uses. Positioning mechanisms ensure optimal heat capture, longevity of the Heat-Exchanger, optimal operating temperature of the Heat-to-Electricity Generator.

The Figures illustrate a heated Ladle and a Heat-to-Electricity Generator, with adjustable positioning to optimize radiant heat capture in a steel recycling mill. The Preheated-Ladle Configuration (FIGS. 1-3) involves a Preheated-Ladle, and the Filled-Ladle Configuration (FIGS. 4-6) involves a Filled-Ladle. Each figure shows the Ladle, the Heat-to-Electricity Generator, and the positioning mechanism (fixed, Overhead Hoist, or Scissor-Lift), highlighting proximity for heat harvesting. The specific version of Heat-to-Electricity Generator isn't paramount to the present invention; therefore it is drafted generically as a box. The Heat-Exchanger is drafted as a volume with tubes and fins running through the volume, which is typical of Heat-Exchangers.

FIG. 1 is a Fixed-Position Heat-to-Electricity Generator with Preheated-Ladle Configuration. The schematic showing a Preheated-Ladle (labeled 101 Heated Ladle) radiating heat at approximately 1400° C. A Heat-to-Electricity Generator (labeled 102 Heat-to-Electricity Generator) is fixed at an optimal distance (e.g., 0.5 m) to absorb radiant heat. The Ladle is a cylindrical steel container, and the Heat-to-Electricity Generator is a rectangular unit with a heat-absorbing surface facing the Ladle. Arrows indicate radiant heat transfer from the Ladle to the Heat-to-Electricity Generator. The setup is stationary, highlighting the simplicity of the combination in a steel recycling mill environment.

Key Elements: 101 Heated Ladle (Preheated-Ladle, ˜200-1400° C.). 102 Heat-to-Electricity Generator (fixed position). Arrows showing radiant heat flow. Generator type (e.g., TRC, ORC, TPV) is not specified for simplicity but indicated as any heat-to-electricity converting system. Illustrates the basic fixed setup for the Preheated-Ladle Configuration, capturing waste radiant heat from a Preheated-Ladle.

FIG. 2 is a Overhead Hoist-Mounted Heat-to-Electricity Generator with Preheated-Ladle Configuration. The schematic showing a Preheated-Ladle (labeled 101 Heated Ladle) radiating heat at ˜1400° C. The Heat-to-Electricity Generator (labeled 102 Heat-to-Electricity Generator) is mounted on an Overhead Hoist (labeled 103 Overhead Hoist) with chains or cables allowing vertical adjustment. The Heat-to-Electricity Generator is positioned proximate to the Ladle (e.g., 0.5 m) for optimal heat capture. Arrows indicate radiant heat transfer and vertical movement of the Heat-to-Electricity Generator. The Overhead Hoist enables dynamic positioning to maximize heat absorption in a steel recycling mill.

Key Elements: 101 Heated Ladle (Preheated-Ladle, ˜1400° C.). 102 Heat-to-Electricity Generator. 103 Overhead Hoist (with chains/cables). Arrows for radiant heat and vertical adjustment. Shows adjustable positioning via Overhead Hoist for the Preheated-Ladle Configuration, emphasizing flexibility in heat harvesting.

FIG. 3 is a Scissor-Lift-Mounted Heat-to-Electricity Generator with Preheated-Ladle Configuration. The schematic showing a Preheated-Ladle (labeled 101 Heated Ladle) radiating heat at ˜1400° C. The Heat-to-Electricity Generator (labeled 102 Heat-to-Electricity Generator) is mounted on a Scissor-Lift (labeled 104 Scissor-Lift) for vertical adjustment. The Heat-to-Electricity Generator is positioned close to the Ladle (e.g., 0.5 m) to absorb radiant heat. Arrows indicate radiant heat transfer and vertical movement of the Scissor-Lift. The setup is in a steel recycling mill, highlighting the Heat-to-Electricity Generator's mobility for optimal heat capture.

Key Elements: 101 Heated Ladle (Preheated-Ladle). 102 Heat-to-Electricity Generator. 104 Scissor-Lift (floor-mounted). Arrows for radiant heat and vertical adjustment. Depicts adjustable positioning via Scissor-Lift for the Preheated-Ladle Configuration, showcasing an alternative method for heat harvesting.

FIG. 4 is a Fixed-Position Heat-to-Electricity Generator with Filled-Ladle Configuration. The schematic showing a Filled-Ladle containing 50,000 pounds of liquid metal (labeled 105 Filled-Ladle) radiating heat at approximately 1593° C. A Heat-to-Electricity Generator (labeled 102 Heat-to-Electricity Generator) is fixed at an optimal distance (e.g., 0.5 m) to absorb intense radiant heat. The Ladle is cylindrical, and the Heat-to-Electricity Generator is a rectangular unit with a heat-absorbing surface. Arrows indicate radiant heat transfer from the Ladle to the Heat-to-Electricity Generator. The stationary setup emphasizes the simple combination in a steel recycling mill.

Key Elements: 101 Heated Ladle (Filled-Ladle, ˜1593° C.). 102 Heat-to-Electricity Generator (fixed position). Arrows showing radiant heat flow. Illustrates the basic fixed setup for the Filled-Ladle Configuration, capturing waste radiant heat from a Filled-Ladle.

FIG. 5 is a Overhead Hoist-Mounted Heat-to-Electricity Generator with Filled-Ladle Configuration. The schematic showing a Filled-Ladle with 50,000 pounds of liquid metal (labeled 105 Filled-Ladle) radiating heat at ˜1593° C. The Heat-to-Electricity Generator (labeled 102 Heat-to-Electricity Generator) is mounted on an Overhead Hoist (labeled 103 Overhead Hoist) with chains or cables for vertical adjustment. The Heat-to-Electricity Generator is positioned proximate to the Ladle (e.g., 0.5 m) for optimal heat capture. Arrows indicate radiant heat transfer and vertical movement. The Overhead Hoist allows dynamic positioning in a steel recycling mill to handle intense heat.

Key Elements: 101 Heated Ladle (Filled-Ladle, ˜1600° C.). 102 Heat-to-Electricity Generator. 103 Overhead Hoist (with chains/cables). Arrows for radiant heat and vertical adjustment. Shows adjustable positioning via Overhead Hoist for the Filled-Ladle Configuration, highlighting flexibility for intense heat harvesting.

FIG. 6: Scissor-Lift-Mounted Heat-to-Electricity Generator with Filled-Ladle Configuration. The schematic showing a Filled-Ladle containing 50,000 pounds of liquid metal (labeled 105 Filled-Ladle) radiating heat at ˜1593° C. The Heat-to-Electricity Generator (labeled 102 Heat-to-Electricity Generator) is mounted on a Scissor-Lift (labeled 104 Scissor-Lift) for vertical adjustment. The Heat-to-Electricity Generator is positioned close to the Ladle (e.g., 0.5 m) to absorb radiant heat. Arrows indicate radiant heat transfer and vertical movement of the Scissor-Lift. The setup in a steel recycling mill emphasizes mobility for optimal heat capture.

Key Elements: 101 Heated Ladle (Filled-Ladle, ˜1593° C.). 102 Heat-to-Electricity Generator. 104 Scissor-Lift (floor-mounted). Arrows for radiant heat and vertical adjustment. Depicts adjustable positioning via Scissor-Lift for the Filled-Ladle Configuration, showcasing an alternative method for intense heat harvesting.

The term “coupled” is defined as connected, although not necessarily directly, and not necessarily mechanically. The use of the word “a” or “an” when used in conjunction with the term “comprising” in the claims and/or the specification may mean “one,” but it is also consistent with the meaning of “one or more” or “at least one.” The terms “comprise” (and any form of comprise, such as “comprises” and “comprising”), “have” (and any form of have, such as “has” and “having”), “include” (and any form of include, such as “includes” and “including”) and “contain” (and any form of contain, such as “contains” and “containing”) are open-ended linking verbs. As a result, a method or device that “comprises,” “has,” “includes” or “contains” one or more steps or elements, possesses those one or more steps or elements, but is not limited to possessing only those one or more elements. Likewise, a step of a method or an element of a device that “comprises,” “has,” “includes” or “contains” one or more features, possesses those one or more features, but is not limited to possessing only those one or more features.

The terms “comprise” (and any form of comprise, such as “comprises” and “comprising”), “have” (and any form of have, such as “has” and “having”), “include” (and any form of include, such as “includes” and “including”), and “contain” (and any form of contain, such as “contains” and “containing”) are open-ended linking verbs. As a result, a method or device that “comprises,” “has,” “includes,” or “contains” one or more steps or elements, possesses those one or more steps or elements, but is not limited to possessing only those one or more elements. Likewise, a step of a method or an element of a device that “comprises,” “has,” “includes,” or “contains” one or more features, possesses those one or more features, but is not limited to possessing only those one or more features. Furthermore, a device or structure that is configured in a certain way is configured in at least that way, but may also be configured in ways that are not listed.

One skilled in the art will readily appreciate that the present invention is well adapted to carry out the objectives and obtain the ends and advantages mentioned, as well as those inherent therein. The embodiments, methods, procedures and techniques described herein are presently representative of the preferred embodiments, are intended to be exemplary, and are not intended as limitations on the scope. Changes therein and other uses will occur to those skilled in the art which are encompassed within the spirit of the invention and are defined by the scope of the appended claims. Although the invention has been described in connection with specific preferred embodiments, it should be understood that the invention as claimed should not be unduly limited to such specific embodiments. Indeed, various modifications of the described modes for carrying out the invention which are obvious to those skilled in the art are intended to be within the scope of the following claims.

What is claimed is:

1. A system for generating electricity from radiant heat in a metal recycling process, comprising:
a heated Ladle radiating heat at 200-2000° C., configured as a Preheated-Ladle or Filled-Ladle;
a Heat-to-Electricity Generator proximate to the Ladle, configured to absorb radiant heat and convert it to electrical energy;
wherein the improvement comprises combining the Ladle and Heat-to-Electricity Generator to capture waste radiant heat, providing electricity generation and reduced factory thermal load to decrease air-conditioning energy consumption.

2. The system of claim 1, wherein the Heat-to-Electricity Generator is fixed at an optimal distance to absorb radiant heat.

3. The system of claim 1, further comprising an Overhead Hoist to adjust the Heat-to-Electricity Generator's position for optimal radiant heat capture.

4. The system of claim 1, further comprising an Overhead Hoist to adjust the Heat-to-Preheated-Ladle and Filled-Ladle relative to the Electricity Generator's position to initiate and optimize radiant heat capture.

5. The system of claim 1, further comprising a Scissor-Lift to vertically adjust the Heat-to-Electricity Generator's position for optimal heat capture.

6. The system of claim 1, wherein the Heat-to-Electricity Generator partially surrounds the Preheated-Ladle and Filled-Ladle to maximize radiant heat absorption.

7. The system of claim 1, wherein the Ladle is configured as a Preheated-Ladle, and the Heat-to-Electricity Generator is positioned vertically above or around to absorb radiant heat.

8. The system of claim 1, wherein the Ladle is configured as a Filled-Ladle, and the Heat-to-Electricity Generator is positioned to absorb radiant heat.

9. The system of claim 1, wherein the electrical energy powers the recycling process, is stored, or transmitted, and radiant heat absorption reduces thermal load.

10. A method for generating electricity from radiant heat in a metal recycling process, comprising:
providing a heated Ladle radiating heat at 200-2000° C., configured as a Preheated-Ladle or Filled-Ladle;
positioning a Heat-to-Electricity Generator proximate to the Ladle to absorb radiant heat;
absorbing radiant heat with the Heat-to-Electricity Generator;
converting radiant heat to electrical energy;
wherein the improvement comprises combining the Ladle and Heat-to-Electricity Generator to capture waste radiant heat, providing electricity generation and reduced thermal load to lower air-conditioning energy.

11. The method of claim 10, further comprising adjusting the Heat-to-Electricity Generator's position using an Overhead Hoist or Scissor-Lift to optimize heat absorption.

12. The method of claim 10, further comprising adjusting the Ladle to a position using an Overhead Hoist or Scissor-Lift to optimize heat absorption by the Heat-to-Electricity Generator.

13. The method of claim 10, further comprising multiple Heat-to-Electricity Generators positioned along the path that the Ladle traverses for the purpose of recycling metal.

14. The method of claim 10, wherein the Ladle is configured as a Preheated-Ladle, and the Heat-to-Electricity Generator is positioned overhead or around to absorb radiant heat.

15. The method of claim 10, wherein the Ladle is configured as a Filled-Ladle, and the Heat-to-Electricity Generator is positioned to absorb radiant heat where the Filled-Ladle is receiving alloy metals to refine the composition of the Liquid-Metal.

16. The method of claim 10, wherein the Heat-to-Electricity Generator is located below and beside the rail system that moves the Ladle between the typical metal recycling stages within the recycling mill.

17. The method of claim 10, wherein the Heat-Exchanger is positioned on a moveable panel that is positioned above the Filled-Ladle for the purpose of reducing thermal loss in the Liquid-Metal.

18. The method of claim 10, further comprising using the electrical energy to power the recycling process, store, or transmit it, and reducing thermal load to lower air-conditioning energy.
